(19) United States
(12) Patent Application Publication
(10) Pub. No.: US 2014/0014897 A1
(43) Pub. Date: Jan. 16, 2014

(54) SEMICONDUCTOR LIGHT EMITTING DEVICE WITH DOPED BUFFER LAYER AND METHOD OF MANUFACTURING THE SAME

(71) Applicant: Samsung Electronics Co., Ltd., Suwon-Si (KR)

(72) Inventors: Jung-sub KIM, Hwaseong-si (KR); Denis SANNIKOV, Suwon-si (KR); Cheol-soo SONE, Seoul (KR); Jin-sub LEE, Suwon-si (KR)

(21) Appl. No.: 13/923,048

(22) Filed: Jun. 20, 2013

(30) Foreign Application Priority Data
Jul. 13, 2012 (KR) 10-2012-0076936

(51) Int. Cl. H01L 33/06

(52) U.S. Cl. CPC H01L 33/06
USPC 257/13

(57) ABSTRACT

According to example embodiments, a semiconductor light emitting device including a doped buffer layer includes a substrate and a buffer layer on the substrate. The doping layer may include aluminum nitride (AlN) and the buffer layer may include a doping layer. An n-type nitride semiconductor layer, an active layer, and a p-type nitride semiconductor layer may be on the buffer layer. An n-side electrode may be on the n-type nitride semiconductor layer. A p-side electrode may be on the p-type nitride semiconductor layer.

### CROSS-REFERENCE TO RELATED APPLICATIONS

This application claims priority under 35 U.S.C. §119 to Korean Patent Application No. 10-2012-0076936, filed on Jul. 13, 2012, in the Korean Intellectual Property Office, the disclosure of which is incorporated herein in its entirety by reference.

### BACKGROUND

Example embodiments of inventive concepts relate to semiconductor devices, and more particularly, to a nitride-based semiconductor light emitting device, HEMT, and/or solar cell including a dopant-containing (or doped) buffer layer configured to grow a nitride semiconductor layer and/or a method of manufacturing the device.

A nitride semiconductor light emitting device may include a plurality of nitride semiconductor layers sequentially formed on a substrate. In particular, a nitride-based semiconductor using a nitride, such as gallium nitride (GaN), has widely been used for photovoltaic materials and electronic devices due to its characteristics and has attracted much attention in related technical fields.

A nitride-based semiconductor light emitting device may include a multilayered structure formed on a substrate, and the multilayered structure may include an n-type nitride semiconductor layer, an active layer, a p-type nitride semiconductor layer. The typical nitride-based semiconductor light emitting device may externally extract light emitted by the active layer and use the light as a light source.

The nitride-based semiconductor light emitting device may use a nitride semiconductor having a desired composition to obtain light having various wavelength ranges. The nitride semiconductor may be grown into single a crystalline semiconductor. Accordingly, occurrence of defects, such as cracks or dislocation, in the nitride semiconductor should be suppressed. To suppress the occurrence of the defects, various methods have been used, such as inserting a superlattice structure or growing a buffer layer at a low temperature.

### SUMMARY

Example embodiments of inventive concepts relate to a semiconductor device such as a nitride-based light emitting device, HEMT, and/or solar cell including a dopant-containing (or doped) buffer layer configured to grow a nitride semiconductor layer.

Example embodiments of inventive concepts also relate to a method of manufacturing a semiconductor device such as a nitride-based light emitting device, a HEMT, and/or solar cell including a process of doping a dopant into a buffer layer to grow a nitride semiconductor layer.

According to example embodiments of inventive concepts, a semiconductor light emitting device includes a doped buffer layer. The device includes: a substrate; a buffer layer on the substrate, the buffer layer including aluminum nitride (AlN), and the buffer layer including a doping layer; an n-type nitride semiconductor layer, an active layer, and a p-type nitride semiconductor layer on the buffer layer; an n-side electrode on the n-type nitride semiconductor layer; and a p-side electrode on the p-type nitride semiconductor layer.

In example embodiments of inventive concepts, the doping layer may have a multilayered structure. The doping layer may include at least two layers.

In example embodiments of inventive concepts, a dopant concentration of the doping layer may be about 10¹⁷/cm³ to 10¹⁹/cm³.

In example embodiments of inventive concepts, the dopant concentration of the doping layer may vary in a thickness direction of the buffer layer, and the dopant concentration may vary between about 10¹⁷/cm³ to 10¹⁹/cm³.

In example embodiments of inventive concepts, a thickness of the buffer layer may be about several hundred nm to about several thousand nm. For example, the buffer layer may have a thickness between about 100 nm to about 3000 nm, inclusive.

In example embodiments of inventive concepts, the doping layer may include a dopant having a different atomic radius than an atomic radius of aluminum (Al).

In example embodiments of inventive concepts, the dopant may include one of silicon (Si), germanium (Ge), indium (In), antimony (Sb), gallium (Ga), phosphorus (P), and arsenic (As).

In example embodiments of inventive concepts, the n-type nitride semiconductor layer may include AlGaN.

In example embodiments of inventive concepts, the p-type nitride semiconductor layer may be formed by doping a p-type dopant into a material expressed by formula: AlₓInyGa_{1-x-y}N (here, 0≦x≦1, 0≦y≦1, and 0≦x+y≦1).

According to example embodiments of inventive concepts, a method of manufacturing a semiconductor light emitting device including a doped buffer layer is provided. The method includes: forming a buffer layer on a substrate, the buffer layer including aluminum nitride (AlN); and forming a doping layer by doping a dopant into the buffer layer, the dopant having a different atomic radius than an atomic radius of aluminum.

In example embodiments of inventive concepts, the forming the doping layer includes forming a multi-layered structure as the doping layer.

In example embodiments of inventive concepts, the forming the doping layer includes doping the dopant into the buffer layer at a dopant concentration that varies in a thickness direction of the buffer layer.

In example embodiments of inventive concepts, the forming the doping layer includes doping one of Si, Ge, In, Sb, Ga, P, and As into the buffer layer.

In example embodiments of inventive concepts, the method may further include forming an n-type nitride semiconductor on the buffer layer. The n-type nitride semiconductor layer may be AlGaN.

In example embodiments of inventive concepts, the method may further include: forming an n-type nitride semiconductor, an active layer, and a p-type nitride semiconductor layer sequentially on the buffer layer; forming an n-side electrode on the n-type nitride semiconductor layer; and forming a p-side electrode on the p-type nitride semiconductor layer.

According example embodiments of inventive concepts, a semiconductor device includes: a substrate; a buffer layer on the substrate, the buffer layer including aluminum nitride (AlN), the buffer layer having at least one doping layer; a plurality of nitride semiconductor layers sequentially stacked on the buffer layer; and a plurality of electrodes connected to the plurality of nitride semiconductor layers.

In example embodiments of inventive concepts, the at least one doping layer may be a plurality of doping layers.

In example embodiments of inventive concepts, the at least one doping layer may include one doping layer having a dopant concentration that varies in a thickness direction of the buffer layer.

In example embodiments of inventive concepts, the plurality of nitride semiconductor layers may include an n-type nitride semiconductor layer on the buffer layer, an active layer on the n-type nitride semiconductor layer, and a p-type nitride semiconductor layer on the active layer. The plurality of electrodes may include an n-side electrode on the n-type nitride semiconductor layer and a p-side electrode on the p-type nitride semiconductor layer.

In example embodiments of inventive concepts, the doping layer may include a doping having a different atomic radius than an atomic radius of aluminum.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing and other features and advantages of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating principles of inventive concepts. In the drawings:

FIG. 1 is a cross-sectional view of a semiconductor light emitting device including a doped buffer layer according to example embodiments of inventive concepts;

FIG. 2 is a cross-sectional view of a semiconductor light emitting device including a buffer layer having a plurality of doping layers according to example embodiments of inventive concepts;

FIG. 3 is a cross-sectional view of a semiconductor light emitting device including a buffer layer having a doping region with a varied dopant concentration according to example embodiments of inventive concepts;

FIGS. 4A through 4G are cross-sectional views illustrating a method of manufacturing a semiconductor light emitting device including a doped buffer layer according to example embodiments of inventive concepts;

FIGS. 5A and 5B are atomic force microscope (AFM) images of the surface of an aluminum nitride (AlN) buffer layer grown to a thickness of about 1 μm;

FIG. 6 is a cross-sectional view of a semiconductor light emitting device including a buffer layer having a plurality of doping regions with a varied dopant concentration according to example embodiments of inventive concepts;

FIGS. 7A to 7B are cross-sectional views of semiconductor light emitting devices including a buffer layer having at least one doping layer and/or doping region according to example embodiments of inventive concepts;

FIGS. 8A and 8B are cross-sectional views of high electron mobility transistors including a buffer layer having at least one doping layer and/or doping region according to example embodiments of inventive concepts; and

FIG. 9 is a cross-sectional view of a solar cell including a buffer layer having at least one doping layer and/or doping region according to example embodiments of inventive concepts.

### DETAILED DESCRIPTION OF THE EMBODIMENTS

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

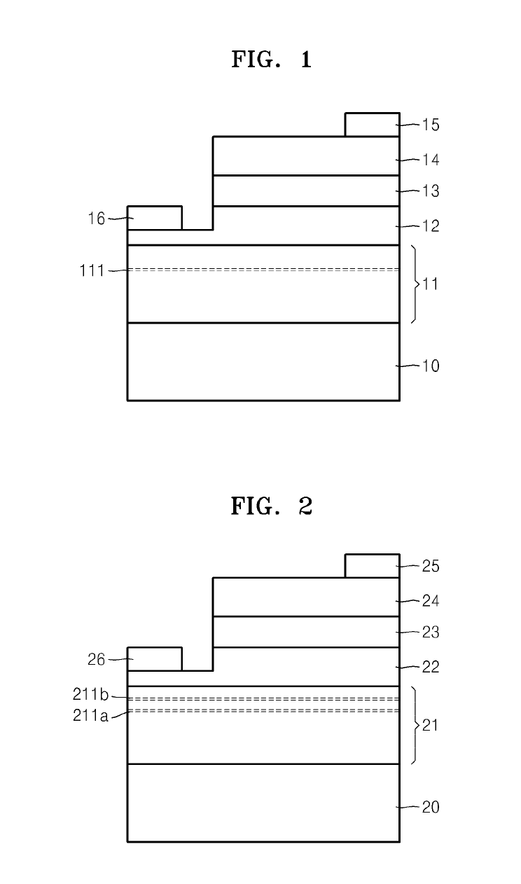

FIG. 1 is a cross-sectional view of a semiconductor light emitting device including a doped buffer layer according to example embodiments of inventive concepts.

Referring to FIG. 1, the semiconductor light emitting device according to example embodiments of inventive concepts may include a substrate 10, a buffer layer 11 formed on the substrate 10, an n-type nitride semiconductor layer 12 formed on the buffer layer 11, an active layer 13 formed on the n-type nitride semiconductor layer 12, and a p-type nitride semiconductor layer 14 formed on the active layer 13. Also, the semiconductor light emitting device may further include electrodes 15 and 16 formed on the n-type nitride semiconductor layer 12 and the p-type nitride semiconductor layer 14, respectively. Here, the buffer layer 11 may include a doping layer 111 to effectively reduce (and/or prevent) occurrence of defects (e.g., cracks and dislocation) of the n-type nitride semiconductor layer 12 formed on the buffer layer 11.

Hereinafter, respective components of the semiconductor light emitting device of FIG. 1, according to example embodiments of inventive concepts, will be described. The following description may be applied to the components of FIG. 1 and the components denoted by the same names in other drawings.

The substrate 10 is not specifically limited and may be any material used to grow a nitride semiconductor material. For example, a sapphire substrate or a semiconductor (e.g., silicon) substrate may be used as the substrate 10. Since sapphire relatively facilitates growth of a nitride semiconductor material and has stable characteristics at a high temperature, sapphire may be used as a substrate material for growing the nitride semiconductor material. In addition, the substrate 10 may alternatively be a silicon (Si) substrate, a silicon carbide (SiC) substrate, a gallium oxide (Ga₂O₃) substrate, magnesium aluminum oxide (MgAl₂O₄) substrate, a magnesium oxide (MgO) substrate, a lithium aluminum oxide (LiAlO₂) substrate, a lithium gallium oxide (LiGaO₂) substrate, or a gallium nitride (GaN) substrate. However, example embodiments of inventive concepts are not limited thereto.

The buffer layer 11 may be formed to alleviate lattice mismatch between the substrate 10 and the nitride semiconductor material to grow the nitride semiconductor material formed on the buffer layer 11. Since a substrate material (e.g., sapphire) may have a different crystalline structure than the nitride semiconductor material, a material for the buffer layer 11 may be selected in consideration of the materials for the substrate 10 and the n-type nitride semiconductor layer 12. The buffer layer 11 may be formed of aluminum nitride (AlN) to a thickness of about several hundred nm to several thousand nm, for example, about 100 nm to about 3000 nm.

When the buffer layer 11 is formed of AlN on the substrate 10, since a material (e.g., sapphire) forming the substrate 10 and AlN are not the same materials, a defective region, such as cracks or dislocation, may occur in the buffer layer 11. In this case, defects may expand from the inside of the buffer layer 11 to the surface thereof, thereby degrading surface roughness and crystallinity of the buffer layer 11. Accordingly, growth of the nitride semiconductor material formed on the buffer layer 11 may be detrimentally affected. To reduce the effect of the defective region, nitride-based light emitting devices according to example embodiments of inventive concepts may include a doping layer 111 in the buffer layer 11. The doping layer 111 may be formed by doping a dopant having a larger or smaller atomic radius than aluminum (Al) into the buffer layer 11 formed of AlN. Specifically, the dopant forming the doping layer 111 may be selected from the group consisting of Si, germanium (Ge), indium (In), antimony (Sb), gallium (Ga), phosphorus (P), or arsenic (As), each of which has a different atomic radius from aluminum.

A region of the buffer layer 11 in which the doping layer 111 is formed is not specifically limited. For example, the doping layer 111 may be formed by doping Si, Ge, In, Sb, Ga, P, or As into the entire buffer layer 11. Alternatively, a doping layer 111 having a single structure may be formed in a limited region of the buffer layer 11. Also, a doping layer 111 having a multi-layered structure may be formed in the buffer layer 11 by alternately forming doped regions formed of Si, Ge, In, Sb, Ga, P, or As and undoped regions.

A dopant concentration of the doping layer 111 may be adjusted within the range of about 10¹⁷/cm³ to about 10¹⁹/cm³, but example embodiments of inventive concepts are not limited thereto. The dopant concentration of the doping layer 111 may be controlled to be uniform throughout the doping layer 111. Alternatively, the doping layer 111 may be formed by varying the dopant concentration in a thickness direction, that is, in a direction in which the buffer layer 11 is grown. For example, the doping layer 111 may be formed by gradually increasing the dopant concentration in the direction in which the buffer layer 11 is grown. Alternatively, the dopant concentration may be increased and then reduced to form the doping layer 111.

The n-type nitride semiconductor layer 12 may be formed by doping an n-type dopant into a material expressed by formula: AlₓIn_{y}Ga_{1-x-y}N (here, 0≦x≦1, 0≦y≦1, and 0≦x+y≦1). For example, the n-type nitride semiconductor layer 12 may be formed by doping an n-type dopant, such as silicon (Si), germanium (Ge), selenium (Se), tellurium (Te), or carbon (C), into a group III-V semiconductor such as aluminum gallium nitride (AlGaN), gallium nitride (GaN), or gallium indium nitride (GaInN).

The active layer 13 may have a multi-quantum well (MQW) structure. The active layer 13 may have a multi-layered structure formed by alternating quantum well layers with quantum barrier layers. As examples of the quantum well layers/quantum barrier layers, a blue light emitting device may have an MQW structure including InGaN/GaN, and an ultraviolet (UV) light emitting device may have an MQW structure including GaN/AlGaN, InAlGaN/InAlGaN, or InGaN/AlGaN. To improve the luminous efficiency of the active layer 13, the depth of quantum wells and the stacked number and thicknesses of the quantum well layers/quantum barrier layers.

The p-type nitride semiconductor layer 14 may be formed by doping a p-type dopant into a material expressed by formula: AlₓInyGa_{1-x-y}N (here, 0≦x≦1, 0≦y≦1, and 0≦x+y≦1). For example, the p-type nitride semiconductor layer 14 may be formed by doping a p-type dopant, such as magnesium (Mg), zinc (Zn), or beryllium (Be), into a group III-V nitride semiconductor such as AlGaN, GaN, or GaInN.

The electrodes 15 and 16 may include an n-side electrode 16 formed on a top surface of the n-type nitride semiconductor layer 12 and a p-side electrode 15 formed on a top surface of the p-type nitride semiconductor layer 14. Here, the p-side electrode 15 may include a transparent electrode and a bonding electrode. The transparent electrode may be formed of a metal or metal alloy such as nickel/gold (Ni/Au), or a transparent conductive oxide such as indium tin oxide (ITO) or cadmium tin oxide (CTO). Although not shown in the drawings, a p-type contact layer may be further formed between the p-type nitride semiconductor layer 14 and the p-side electrode 15. The p-type contact layer may be formed of, for example, p-type GaN.

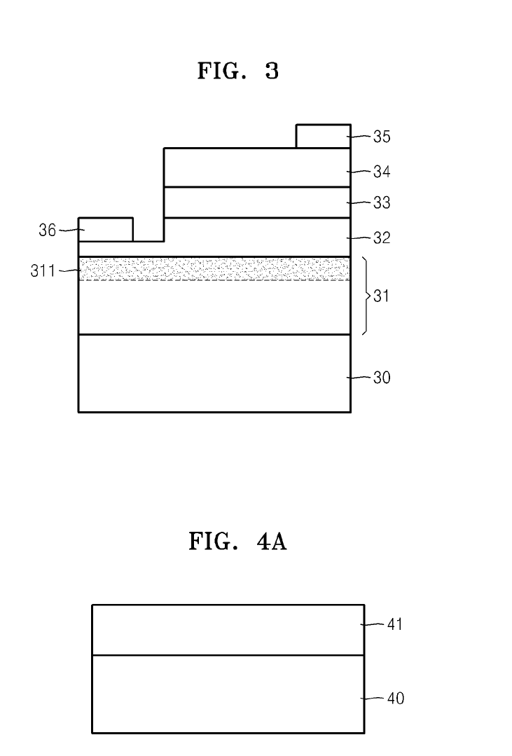

FIG. 2 is a cross-sectional view of a semiconductor light emitting device including a buffer layer having a plurality of doping layers, according to example embodiments of inventive concepts.

Referring to FIG. 2, the semiconductor light emitting device may include a substrate 20, a buffer layer 21 formed on the substrate 20, and an n-type nitride semiconductor layer 22, an active layer 23, and a p-type nitride semiconductor layer 24 sequentially formed on the buffer layer 21. Also, the semiconductor light emitting device may further include electrodes 25 and 26 formed on the n-type nitride semiconductor layer 22 and the p-type nitride semiconductor layer 24, respectively.

Referring to FIG. 2, a first doping layer 211a and a second doping layer 211b may be formed in the buffer layer 21. Each of the doping layers 211a and 211b may be formed by doping a dopant having a different atomic radius from Al into the buffer layer 21 formed of AlN. Here, the dopant may be Si, Ge, In, Sb, Ga, P or As. Each of the doping layers 211a and 211b may be formed without position limitations in the buffer layer 21. Here, although FIG. 2 illustrates two doping layers 211a and 211b formed in the buffer layer 21, a larger number of doping layers may be formed. The first and second doping layers 211a and 211b may have the same dopant concentration or different dopant concentrations.

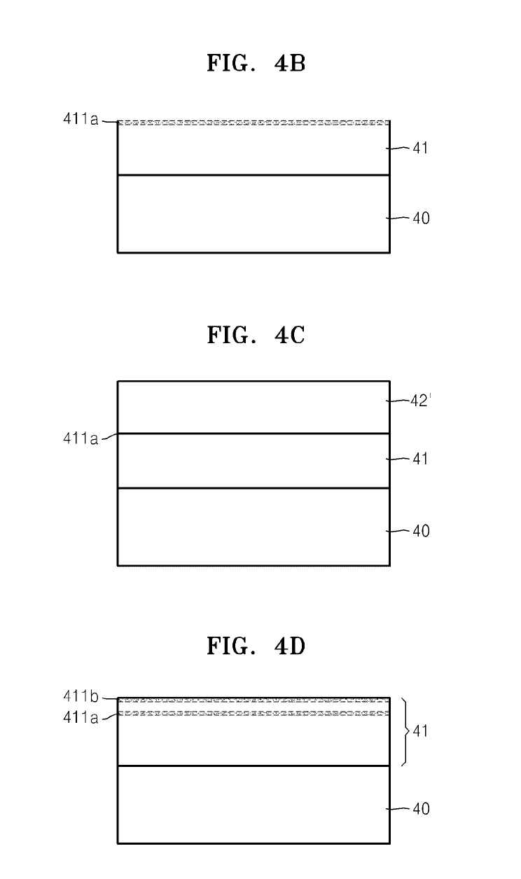

FIG. 3 is a cross-sectional view of a semiconductor light emitting device including a buffer layer having a doping region with a varied dopant concentration according to example embodiments of inventive concepts.

Referring to FIG. 3, the semiconductor light emitting device may include a substrate 30, a buffer layer 31 formed on the substrate 30, and an n-type nitride semiconductor layer 32, an active layer 33, and a p-type nitride semiconductor layer 34 sequentially formed on the buffer layer 31. Also, the semiconductor light emitting device may further include electrodes 35 and 36 formed on the n-type nitride semiconductor layer 32 and the p-type nitride semiconductor layer 34, respectively.

FIG. 3 illustrates the doping layer 311 formed throughout a relatively wide region of the buffer layer 31. Here, the dopant concentration of the doping layer 311 may be uniform throughout the entire doping layer 311 or varied in a direction in which the buffer layer 31 is formed. For example, the dopant concentration of the doping layer 311 may gradually increase or decrease in a thickness direction, that is, in the direction in which the buffer layer 31 is formed. Also, the dopant concentration of the doping layer 311 may increase and then decrease in the direction in which the buffer layer 31 is formed. In this case, the dopant concentration of the doing layer 311 may be controlled within the range of about 10¹⁷/cm³ to 10¹⁹/cm³.

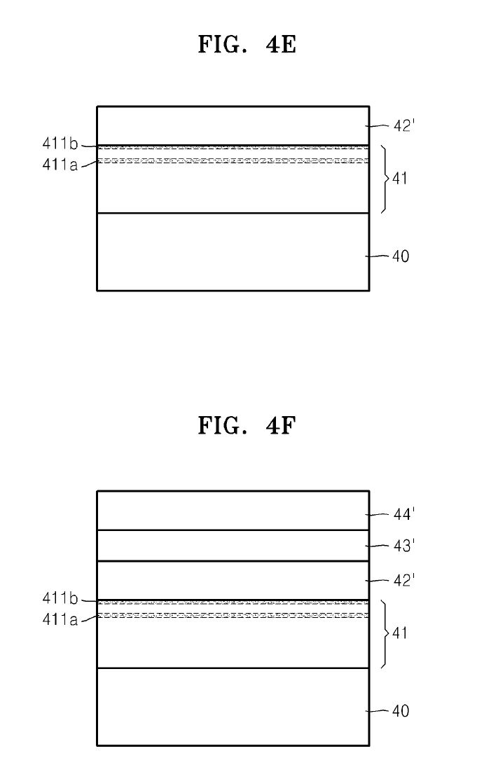

FIGS. 4A through 4G are cross-sectional views illustrating a method of manufacturing a semiconductor light emitting device including a doped buffer layer according to example embodiments of inventive concepts.

Referring to FIG. 4A, a buffer layer 41 may be formed on a substrate 40. For example, an AlN buffer layer may be formed on a sapphire substrate. The buffer layer 41 may be formed using a metal organic chemical vapor deposition (MOCVD) process, a molecular beam epitaxy (MBE) process, or a hybrid vapor phase epitaxy (HVPE) process, but example embodiments of inventive concepts are not limited thereto.

Referring to FIG. 4B, a first doping layer 411a may be formed in the buffer layer 41 by doping a dopant having a different atomic radius from Al. The dopant may be Si, Ga, In, Sb, Ga, P, or As. A dopant concentration of the doping layer 411a may be adjusted within the range of about 10¹⁷/cm³ to 10¹⁹/cm³, but example embodiments of inventive concepts are not limited thereto. The first doping layer 41 la may be formed during a doping process after forming the buffer layer 41. Alternatively, during the formation of the buffer layer 41, the first doping layer 41 la may be formed by doping a dopant.

Referring to FIG. 4C, an n-type nitride semiconductor layer 42′ may be grown on the buffer layer 41 after the first doping layer 411a is formed. The n-type nitride semiconductor layer 42′ may be grown directly on the first doping layer 411a. Alternatively, another undoped AlN portion of the buffer layer 41 may be grown on the first doping layer 41 la before the n-type nitride semiconductor layer 42′ is grown on the buffer layer 41. For example, FIG. 1 of the present application illustrates an n-type nitride semiconductor layer 12 grown on a buffer layer 11, where an undoped portion of the buffer layer 11 is between the first doping layer 111a and the n-type nitride semiconductor layer 12.

Referring to FIG. 4D, after forming the first doping layer 411a in the buffer layer 41, a second doping layer 411b may be further formed. The second doping layer 411b may be formed using the same method as the first doping layer 411a. The second doping layer 411b may be formed to have the same dopant concentration as or a different dopant concentration than the first doping layer 411a.

Referring to FIG. 4E, an n-type nitride semiconductor layer 42′ may be grown on the buffer layer 41 after the second doping layer 411b is formed. By forming the doping layers 411a and 411b in the buffer layer 41, a buffer layer 41 having a lower defect density may be formed as compared with a case in which the doping layers 411a and 411b are not formed. Accordingly, the n-type nitride semiconductor layer 42′ formed on the buffer layer 41 may be grown into a stable structure having a reduced defect density.

The n-type nitride semiconductor layer 42′ may be grown directly on the second doping layer 411b. Alternatively, another undoped AlN portion of the buffer layer 41 may be grown on the second doping layer 411b before the n-type nitride semiconductor layer 42′ is grown on the buffer layer 41. For example, FIG. 2 of the present application illustrates an n-type nitride semiconductor layer 22 grown on a buffer layer 21, where an undoped portion of the buffer layer 21 is between the second doping layer 211b and the n-type nitride semiconductor layer 22.

While FIG. 2 of the present application illustrates a buffer layer 21 with two doping layers 211a and 211b alternately formed between undoped portions of the buffer layer 21, example embodiments of inventive concepts are not limited thereto. A buffer layer may 21 may include more than two doping layers (e.g., 211a, 211b) and undoped portions of buffer layer alternately formed between the n-type nitride semiconductor layer 22 and substrate 20.

Referring to FIG. 4F, an active layer 43′ and a p-type nitride semiconductor layer 44′ may be formed on the n-type nitride semiconductor layer 42′.

As shown in FIG. 4G, the p-type nitride semiconductor layer 44′, the active layer 43′, and the n-type nitride semiconductor layer 42′ may be partially removed to expose the n-type nitride semiconductor layer 42′.

Partially removing the p-type nitride semiconductor layer 44′, the active layer 43′, and the n-type semiconductor layer 42′ may include a patterning process that forms the p-type nitride semiconductor layer 44, the active layer 43, and the n-type semiconductor layer 42. An n-side electrode 46 may be formed on a top surface of the n-type nitride semiconductor layer 42 and a p-side electrode 45 may be formed on a top surface of the p-type nitride semiconductor layer 44. Here, the p-side electrode 45 may include a transparent electrode and a bonding electrode.

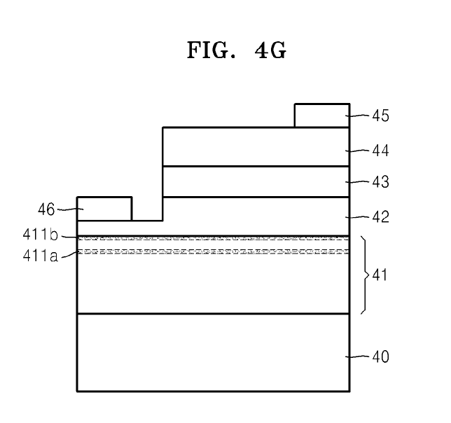

FIGS. 5A and 5B are atomic force microscope (AFM) images of the surface of an AlN buffer layer grown to a thickness of about 1 μm. FIG. 5A is an AFM image of a surface of a grown AlN buffer layer, and FIG. 5B is an AFM image of a surface of the AlN buffer layer into which silicon was doped at a concentration of about 5×10¹⁷/cm³. When the surface roughness of each of the AlN buffer layers were measured, a central portion of the AlN buffer layer that was not doped with silicon had a surface roughness of about 1.9 nm, while the central portion of the Si-doped AlN buffer layer had an improved surface roughness of about 0.8 nm.

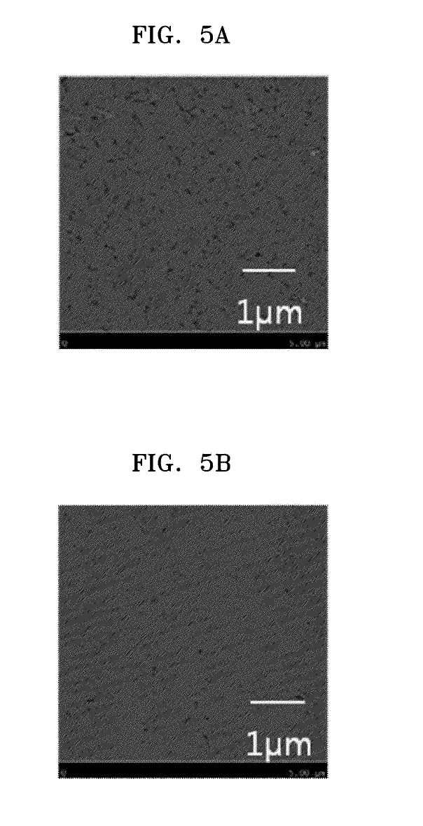

FIG. 6 is a cross-sectional view of a semiconductor light emitting device including a buffer layer having a plurality of doping regions with a varied dopant concentration according to example embodiments of inventive concepts.

Referring to FIG. 6, the semiconductor light emitting device may include a substrate 60, a buffer layer 61 formed on the substrate 60, and an n-type nitride semiconductor layer 62, an active layer 63, and a p-type nitride semiconductor layer 64 sequentially formed on the buffer layer 61. Also, the semiconductor light emitting device may further include electrodes 65 and 66 formed on the n-type nitride semiconductor layer 62 and the p-type nitride semiconductor layer 64, respectively.

FIG. 6 illustrates the buffer layer 61 may include a plurality of doping layers 311a and 311b that are spaced apart vertically and formed throughout a relatively wide region of the buffer layer 61. Here, the dopant concentration of the doping layers 611a and 611b may be the same or different. Additionally, the dopant concentration of the doping layers 611a and 611b may be uniform throughout the entire doping layers 611a and 611b or varied in a direction in which the buffer layer 61 is formed. For example, the dopant concentration of the doping layers 611a and/or 611b may gradually increase or decrease in a thickness direction, that is, in the direction in which the buffer layer 61 is formed. Also, the dopant concentration of the doping layers 611a and/or 611b may increase and then decrease in the direction in which the buffer layer 61 is formed. In this case, the dopant concentration of the doing layers 611a and/or 611b may be controlled within the range of about 10¹⁷/cm³ to 10¹⁹/cm³.

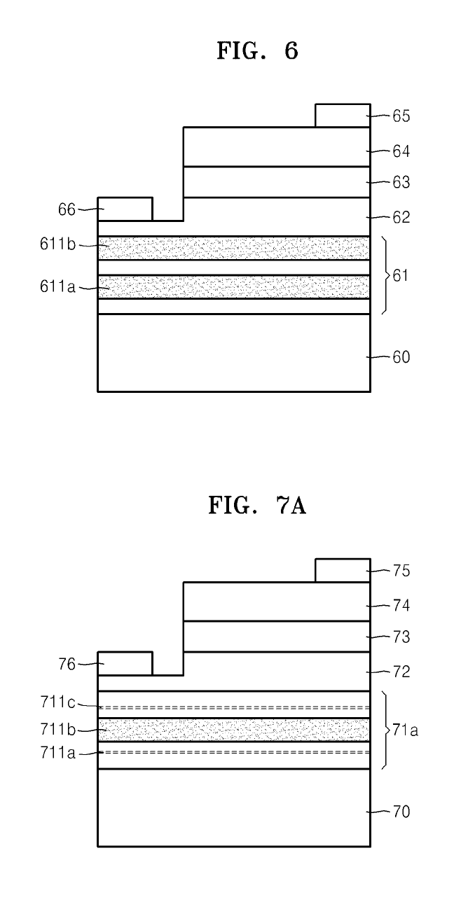

FIGS. 7A to 7B are cross-sectional views of semiconductor light emitting devices including a buffer layer having at least one doping layer and/or doping region according to example embodiments of inventive concepts.

Referring to FIG. 7A, a semiconductor light emitting device according to example embodiments of inventive concepts may include a substrate 70, a buffer layer 71a formed on the substrate 70, and an n-type nitride semiconductor layer 72, an active layer 73, and a p-type nitride semiconductor layer 74 sequentially formed on the buffer layer 71a. Also, the semiconductor light emitting device may further include electrodes 75 and 76 formed on the n-type nitride semiconductor layer 72 and the p-type nitride semiconductor layer 74, respectively.

The buffer layer 71a in the semiconductor light emitting device of FIG. 7A may be similar to the buffer layers 11, 21, 31, and 61 described previously with respect to FIGS. 1 to 3 and 6, except the buffer layer 71a in FIG. 7A may include a doping layers 711a, 711b, 711c alternately formed between undoped portions of the buffer layer 71a. The doping layers 711a and 711c may be the same as the doping layers 111, 211a and 211b described previously with respect to FIGS. 1-2. The doping layer 711b may be the same as the doping layers 311, 611a, and 611b described previously with respect to FIGS. 3 and 6.

Referring to FIG. 7B, a semiconductor light emitting device according to example embodiments of inventive concepts may include a substrate 70, a buffer layer 71b formed on the substrate 70, and an n-type nitride semiconductor layer 72, an active layer 73, and a p-type nitride semiconductor layer 74 sequentially formed on the buffer layer 71b. Also, the semiconductor light emitting device may further include electrodes 75 and 76 formed on the n-type nitride semiconductor layer 72 and the p-type nitride semiconductor layer 74, respectively.

The buffer layer 71b in the semiconductor light emitting device of FIG. 7B may be similar to the buffer layers 11, 21, 31, and 61 described previously with respect to FIGS. 1 to 3 and 6, except the buffer layer 71b in FIG. 7B may include a doping layers 712a, 712b, 712c alternately formed between undoped portions of the buffer layer 71b. The doping layers 712a and 712c may be the same as the doping layers 311, 611a, and 611b described previously with respect to FIGS. 3 and 6. The doping layer 712b may be the same as the doping layers 111, 211a and 211b described previously with respect to FIGS. 1-2.

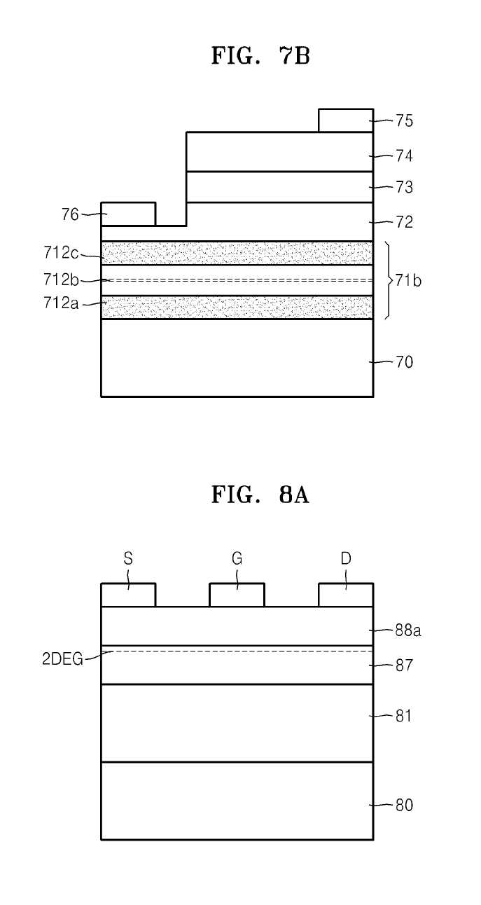

FIGS. 8A and 8B are cross-sectional views of high electron mobility transistors including a buffer layer having at least one doping layer and/or doping region according to example embodiments of inventive concepts.

Referring to FIG. 8A, a high electron mobility transistor (HEMT) according to example embodiments of inventive concepts may include a substrate 80, a buffer layer 81 formed on the substrate 80, a channel layer 87 formed on the buffer layer 71, and a channel supply layer 88a formed on the channel layer 87. Source S, Gate G, and Drain D electrodes may be spaced apart on the channel supply layer 88a.

The substrate 90 may include the same materials as the substrate 10 described previously in FIG. 1. The buffer layer 81 may be formed the same as any one of the foregoing buffer layers 11, 21, 31, 41, 61, 71a, and 71b described previously with respect to FIGS. 1, 2, 3, 4, 6, 7A, and 7B.

The channel layer 87 may include a group III-V nitride semiconductor such as gallium nitride (GaN) or gallium indium nitride (GaInN). The channel supply layer 88a may be formed by growing a group III-V nitride semiconductor such as AlGaN on the channel layer 87. The channel supply layer 88a may have a higher polarizability than a polarizability of the channel layer 87. The channel supply layer 88a may be configured to induce a two dimensional electron gas (2DEG) in the channel layer 87 due to a polarizability difference between the channel supply layer 88a and the channel layer 87.

Referring to FIG. 8B, a HEMT according to example embodiments of inventive concepts may be the same as the HEMT shown in FIG. 8A, except a depletion-forming layer 89 may be formed between the gate electrode G and the channel supply layer 88b. The depletion-forming layer 89 may include a p-type nitride semiconductor such as p-doped AlGaN.

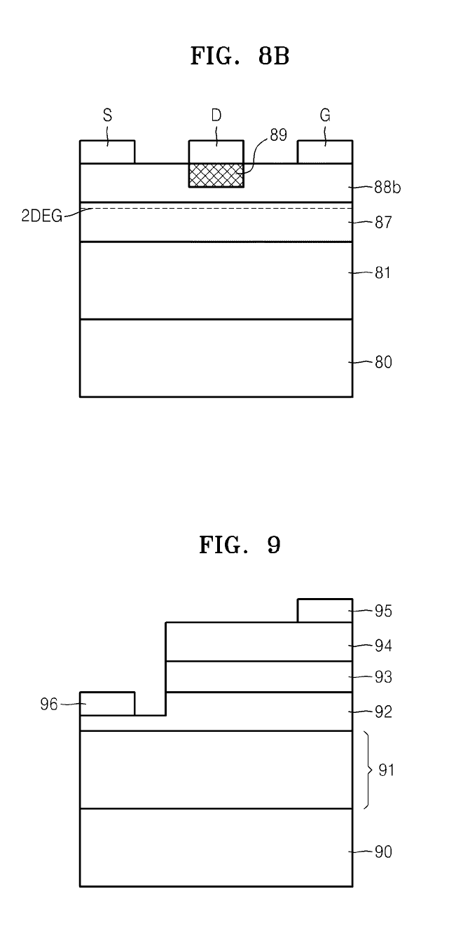

FIG. 9 is a cross-sectional view of a solar cell including a buffer layer having at least one doping layer and/or doping region according to example embodiments of inventive concepts.

Referring to FIG. 9, a solar cell according to example embodiments of inventive concepts may include a substrate 90 and a buffer layer 91 formed on the substrate 90. Also, an n-type nitride semiconductor layer 92 formed on the buffer layer 91, an n-type nitride semiconductor layer 92, an active layer 93, and a p-type nitride semiconductor layer 64 may be sequentially formed on the buffer layer 91. Also, the solar cell may further include electrodes 95 and 96 formed on the n-type nitride semiconductor layer 92 and the p-type nitride semiconductor layer 94, respectively.

The substrate 90 may include the same materials as the substrate 10 described previously in FIG. 1. The buffer layer 81 may be formed the same as any one of the foregoing buffer layers 11, 21, 31, 41, 61, 71a, and 71b described previously with respect to FIGS. 1, 2, 3, 4, 6, 7A, and 7B.

The n-type nitride semiconductor layer 92 may be formed by doping an n-type dopant into a group III-V semiconductor such as aluminum gallium nitride (AlGaN), gallium nitride (GaN), or gallium indium nitride (GaInN).

The active layer 93 may have a multi-quantum well (MQW) structure. The active layer 13 may have a multi-layered structure formed by alternating quantum well layers with quantum barrier layers. As examples of the quantum well layers/quantum barrier layers, the active layer 93 may have an MQW structure including alternating InGaN/GaN, GaN/AlGaN, InAlGaN/InAlGaN, or InGaN/AlGaN layers.

The p-type nitride semiconductor layer 94 may be formed by doping a p-type dopant into a group III-V nitride semiconductor such as AlGaN, GaN, or GaInN.

In semiconductor light emitting devices, HEMTs, and/or solar cells according to example embodiments of inventive concepts, a doping layer may be formed by doping a dopant (e.g., Si, Ge, In, Sb, Ga, P, or As) having a different atomic radius from Al into the buffer layer, thereby reducing (and/or preventing) occurrence of lattice defects in the buffer layer and improving the surface roughness of the buffer layer. Thus, defects of a nitride semiconductor layer formed on the buffer layer can be reduced (and/or suppressed), and the crystallinity of the nitride semiconductor layer can be enhanced. Also, a lattice constant of the buffer layer can be changed due to the dopant, thereby varying a stress state of a substrates or a warpage degree. A uniform thin layer can be grown using this point. Also, a nitride semiconductor layer having more stable characteristics can be formed without performing an additional complicated process of forming a superlattice structure including AlGaN/AlN.

It should be understood that example embodiments described of inventive concepts described herein should be considered in a descriptive sense only and not for purposes of limitation. Descriptions of features or aspects within each semiconductor light emitting device, HEMT, and solar cell and/or method of manufacturing the same according to example embodiments of inventive concepts should typically be considered as available for other similar features or aspects in other devices or methods according to example embodiments.

While some example embodiments of inventive concepts have been particularly shown and described, it will be understood by one of ordinary skill in the art that variations in form and detail may be made therein without departing from the spirit and scope of the claims.

1. A semiconductor light emitting device including a doped buffer layer, the device comprising:
a substrate;
a buffer layer on the substrate,
the buffer layer including aluminum nitride (AlN), and
the buffer layer including a doping layer;
an n-type nitride semiconductor layer, an active layer, and a p-type nitride semiconductor layer on the buffer layer; and
an n-side electrode on the n-type nitride semiconductor layer; and a p-side electrode on the p-type nitride semiconductor layer.

2. The device of claim 1, wherein the doping layer has a multilayered structure.

3. The device of claim 1, wherein a dopant concentration of the doping layer is about 10¹⁷/cm³ to 10¹⁹/cm³.

4. The device of claim 3, wherein the dopant concentration of the doping layer varies in a thickness direction of the buffer layer.

5. The device of claim 1, wherein a thickness of the buffer layer is about 100 nm to about 3000 nm.

6. The device of claim 1, wherein the doping layer includes a dopant having a different atomic radius than an atomic radius of aluminum (Al).

7. The device of claim 6, wherein the dopant includes one of silicon (Si), germanium (Ge), indium (In), antimony (Sb), gallium (Ga), phosphorus (P), and arsenic (As).

8. The device of claim 1, wherein the n-type nitride semiconductor layer includes aluminum gallium nitride (AlGaN).

9.-15. (canceled)

16. A semiconductor device comprising:
a substrate;
a buffer layer on the substrate,
the buffer layer including aluminum nitride (AlN),
the buffer layer having at least one doping layer;
a plurality of nitride semiconductor layers sequentially stacked on the buffer layer; and
a plurality of electrodes connected to the plurality of nitride semiconductor layers.

17. The device of claim 16, wherein the at least one doping layer is a plurality of doping layers.

18. The device of claim 16, wherein the at least one doping layer includes one doping layer having a dopant concentration that varies in a thickness direction of the buffer layer.

19. The device of claim 16, wherein
the plurality of nitride semiconductor layers includes a n-type nitride semiconductor layer on the buffer layer, an active layer on the n-type nitride semiconductor layer, and a p-type nitride semiconductor layer on the active layer;
the plurality of electrodes include a n-side electrode and a p-side electrode;
the n-side electrode is on the n-type nitride semiconductor layer; and
the p-side electrode is on the p-type nitride semiconductor layer.

20. The device of claim 16, wherein the doping layer includes a dopant having a different atomic radius than an atomic radius of aluminum (Al).
